(19) United States
(12) Patent Application Publication
(10) Pub. No.: US 2009/0189147 A1
(43) Pub. Date: Jul. 30, 2009

(54) Organic transistor comprising a self-aligning gate electrode, and method for the production thereof

(76) Inventors: Walter Fix, Nümberg (DE); Jürgen Ficker, Erlangen (DE)

Correspondence Address: CARELLA, BYRNE, BAIN, GILFILLAN, CECCHI,;STEWART & OLSTEIN, 5 BECKER FARM ROAD, ROSELAND, NJ, 07068, US

(21) Appl. No.: 10/585,775

(22) PCT Filed: Jan. 13, 2005
(86) PCT No.: PCT/DE2005/000039

§ 371 Date: Sep. 28, 2007

(30) Foreign Application Priority Data
Jan. 14, 2004 (DE) 10 2004 002 024.8

(51) Int. Cl. H01L 51/10; H01L 21/336; H01L 29/78; H01L 51/40

(52) U.S. Cl. 257/40; 438/164; 257/347; 438/99; 257/E21.409; 257/E29.255; 257/E51.007

(57) ABSTRACT

An unpatterned semiconductor layer is applied to a substrate for the production of an organic transistor. An insulator is arranged on the semiconductor layer wherein at least the insulator layer is patterned, so that at least source and drain electrode layers can be formed subsequently. The source and drain electrode layers are formed after the patterning of at least the insulator layer to ensures that an overlap of both a gate electrode layer and the source and drain electrode layers is essentially avoided.

The present invention relates to an organic transistor and to a method for the production of the organic transistor. In particular, the present invention relates to an organic transistor comprising a self-aligning gate electrode, and to a method for the production of said organic transistor.

Transistors are the central components of any electronic circuit, so that in general the complexity and the costs for the production of the transistors and also the properties of the transistors in electronic circuits largely have a determining influence on these circuits. This likewise applies to the field of organic circuits, which have been made possible by the development of electrically conductive and electrically semiconducting materials, in particular polymers. Organic transistors, by analogy with traditional transistors, are likewise composed of different layers including insulator layer, semiconductor layer and also source, drain and gate electrode layers.

At the present time, printing methods are preferred for the production of organic components and in particular organic transistors, said printing methods being economically advantageous and permitting the production of transistors in few process steps. What is characteristic of printing methods of the prior art is the progress of the patterned application or printing on of the functional organic layers.

Particularly in the case of the top gate construction of transistors, that is to say if the gate electrode layer is applied last to the transistor structure, it is necessary for the gate electrode layer to be aligned with respect to the source or respectively drain electrode layer with sufficient accuracy. The accuracy of the alignment of the gate electrode layer determines the size of an overlap region between gate electrode layer and source or respectively drain electrode layer. Said overlap region, which is typically a few tens of μm, critically influences the parasitic capacitances of the integrated circuits constructed with the aid of the conventional organic transistors. Such parasitic capacitances are disadvantageous primarily when the frequency of the circuits is increased and fixedly determine, inter alia, an upper limiting frequency for the operation of circuits. Consequently, the parasitic capacitances of the transistors crucially define the performance and quality of circuits. It has not been economically possible hitherto in the context of series production to decrease the overlap region of a few tens of μm that is typical in the case of conventional production methods.

The quality and thus the performance of organic transistors is furthermore determined, moreover, by the homogeneity of the functional layers. In this case, it should be noted that the term of the homogeneity of a layer encompasses in particular a constant thickness or a constant thickness parameter of a layer. During the application of a layer that is to be applied to an uneven base, for example a patterned layer that is printed in multiple steps, the application may inevitably result in a layer having non-optimum homogeneity. This is to be taken into account particularly in the case of the alternative bottom gate construction of transistors, that is to say that the gate electrode layer is applied first to the transistor structure, if the insulator layer is to be applied to a patterned gate electrode layer. A sufficient homogeneity cannot be ensured in the case of these process steps.

It is an object of the invention to provide a method for the production of an organic transistor which makes it possible to form a source or respectively drain electrode layer in such a way that an overlap between the source or respectively drain electrode layer and a gate electrode layer is avoided, so that parasitic effects due to source or respectively drain electrode layer and a gate electrode layer are as small as possible.

A further object of the invention is to ensure the homogeneity of the functional layers of the organic transistor.

The object of the invention is achieved by means of a production method in accordance with claim 1 and by means of an organic transistor in accordance with claim 11.

The present invention accordingly relates to a production method for an organic transistor. For the production of the organic transistor according to the invention, a substrate is provided, on which an unpatterned semiconductor layer is applied, on which in turn an unpatterned insulator layer is arranged. At least the insulator layer is patterned, so that at least source and drain electrode layers can subsequently be formed.

The layers arranged in unpatterned fashion on the substrate are particularly advantageous since these layers can be formed homogeneously without any problems. A patterning that disturbs the homogeneity of the layers is not present.

Advantageous refinements of the invention emerge from the dependent claims.

According to the invention, an unpatterned gate electrode layer is furthermore arranged on the insulator layer of the substrate provided. The insulator layer and the gate electrode layer are patterned jointly in order to uncover defined regions of the formerly covered semiconductor layer. The uncovered regions of the semiconductor layer are subsequently doped in order to make the latter permanently conductive, so that the doped regions may serve as source and drain electrode layers. The uncovered regions of the semiconductor layer may be doped by means of a doping chemical.

According to the invention, an unpatterned gate electrode layer is furthermore arranged on the insulator layer. The semiconductor layer, the insulator layer and also the gate electrode layer are patterned jointly, so that defined regions of the substrate formerly covered by the layers are uncovered. Source and drain electrode layers are formed by applying an electrically conductive substance to the uncovered regions.

According to the invention, the semiconductor layer and also the insulator layer may likewise, so that defined regions of the substrate formerly covered by the layers are uncovered. Afterward, both the source and drain electrode layers and the gate electrode layer are formed by applying an electrically conductive substance. For this purpose, the conductive substance is applied to the uncovered regions of the substrate and also to the insulator layer.

The formation of the source and drain electrode layers after the patterning of at least the insulator layer ensures that an overlap both of the gate electrode layer and of the source and drain electrode layers is essentially avoided.

The patterning is preferably effected by means of a laser, a lithographic process or a printing lithographic process.

The substrate is advantageously an organic substrate, preferably a plastic film, and in particular a polyester or an organic film. The semiconductor layer is advantageously based on an organic semiconducting substance. The semiconductor layer may be formed in particular from one of the polymeric substances such as, for example, polyalkylthiophene, polydihexylterthiophene (PDHTT) and polyfluorene derivatives. The insulator layer is advantageously an organic electrically insulating insulator layer.

In accordance with a further aspect of the invention, an organic transistor is provided. The organic transistor is producible in accordance with the method described above. In particular, an organic transistor of this type is distinguished by the fact that the source and drain electrode layers and the gate electrode layer essentially do not overlap.

Details and preferred embodiments of the subject matter according to the invention emerge from the dependent claims and also the drawings, with reference to which exemplary embodiments are explained in detail below, so that the subject matter according to the invention will become clearly evident. In the drawings:

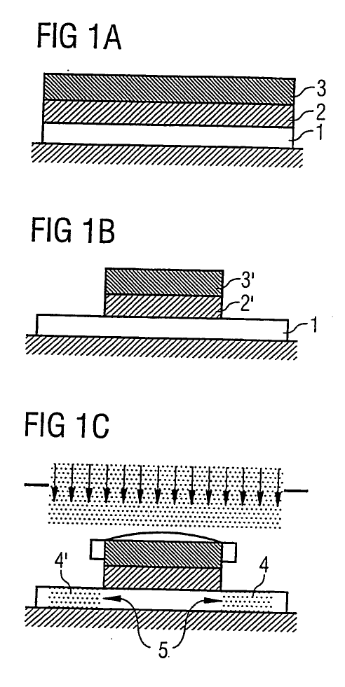

FIG. 1a shows an arrangement of unpatterned functional layers of a typical organic transistor;

FIG. 1b shows a first patterning of the functional layers in accordance with the first embodiment of the invention;

FIG. 1c shows a second patterning of the functional layers in accordance with the first embodiment of the invention;

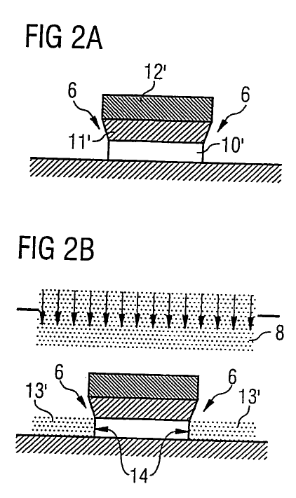

FIG. 2a shows a first patterning of the functional layers in accordance with the second embodiment of the invention;

FIG. 2b shows a second patterning of the functional layers in accordance with the second embodiment of the invention;

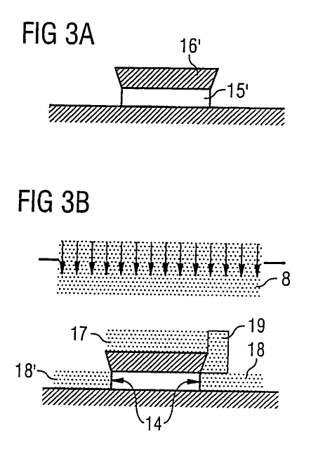

FIG. 3a shows a first patterning of the functional layers in accordance with a third embodiment of the invention;

FIG. 3b shows a second patterning of the functional layers in accordance with a third embodiment of the invention.

A first embodiment for the production of an organic transistor according to the invention is illustrated by way of example in FIG. 1a to FIG. 1c.

In accordance with FIG. 1, a homogeneous, unpatterned semiconductor layer 1 is applied on a substrate in a production process. In the further course of the procedure, an unpatterned insulator layer 2 is applied to the semiconductor layer 1, and then an unpatterned gate electrode layer 3 is applied. The large-area unpatterned application of the functional layers on the substrate ensures that the layers have a high quality, that is to say in particular an essentially optimum homogeneity and essentially a constant thickness over the application area.

The substrate, which serves as a carrier at least for the organic transistor, is preferably formed from flexible material. By way of example, thin glasses and plastic films are taken into consideration for this purpose. Furthermore, from the area of plastic films, use is preferably made of polyethylene terephthalate, polyimide and polyester films. The thickness of the substrate essentially has a determining influence on the total thickness of the component since the layer thicknesses of the functional layers applied to the substrate are orders of magnitude smaller. A typical substrate thickness lies in the range of 0.05 to 0.5 mm.

The term “organic materials” is to be understood to mean all types of organic, organometallic and/or inorganic plastics with the exception of the traditional semiconductor materials based on germanium, silicon, etc. Furthermore, the term “organic material” is likewise not intended to be restricted to carbon-containing material, rather materials such as silicones are likewise possible. Moreover, “small molecules” can likewise be used in addition to polymeric and oligomeric substances.

Thus, the functional semiconductor layers 1 may comprise for example polythiophenes, polyalkylthiophene, polydihexylterthiophene (PDHTT), polythienylenevinylenes, polyfluorene derivates or conjugated polymers, to mention a selection of possible substances. The semiconductor layer 1 may likewise be processed from solution by spin-coating, blade coating or printing.

The gate electrode layer may be realized from a wide variety of substances, that is to say that organic and metallic substances are taken into consideration depending on the choice of production process and requirements made of the gate electrode layer.

The unpatterned insulator layer 2 applied on the substrate and gate electrode layer 3 that are illustrated in FIG. 1a are subsequently patterned jointly. The patterning may be effected for example by means of removal using a laser or, as an alternative, by means of protective resist in lithographic or printing lithographic processes.

FIG. 1b shows the formation of the functional layers after the patterning described above. Both the insulator layer 2′ and the gate electrode layer 3′ are present in patterned fashion, the semiconductor layer 1 essentially remaining unaffected by the patterning and having uncovered regions that are no longer covered by the patterned insulator layer 2′ and the patterned gate electrode layer 3′.

In accordance with FIG. 1c, the source and drain electrode layers 4, 4′ are formed subsequent to the joint patterning of the insulator layer 2′ and of the gate electrode layer 3′. The formation of the source and drain electrode layers 4, 4′ is achieved by doping the regions of the semiconductor substrate 1 that are uncovered as a result of the patterning of the insulator layer 2′ and of the gate electrode layer 3′. The doping may be obtained for example by means of a direct printing process by the application of a doping chemical to the uncovered regions of the semiconductor 1. In this case, the doping chemical acts on the semiconductor 1 and produces a permanent conductivity, so that the doped regions of the semiconductor 1 are available as source and drain electrode layers 4 and 4′. As an alternative, the printing process may be effected indirectly by firstly printing on a patterned protective layer, so that the action of the doping chemical is restricted to regions that are not covered by a protective layer.

In a specific embodiment of the above-described production or respectively the above-described transistor resulting from the production, the substrate is formed from polyester film. Appropriate semiconductor material is, in particular, polyalkylthiophene, preferably polydihexylterthiophene (PDHTT), or polyfluorene derivates, which can be spun on or printed on. Furthermore, a polymeric insulator layer and an organic or metallic gate electrode layer are used. The gate electrode layer and the insulator layer can be patterned jointly by means of a laser. The uncovered regions of the semiconductor layer are subsequently doped by means of iron chloride FeCl₃ in acetonitrile.

A second embodiment for the production of an organic transistor according to the invention is illustrated by way of example in FIG. 2a and FIG. 2b.

The starting point is, as described above with regard to FIG. 1a, a substrate, to which an unpatterned, homogeneous semiconductor layer 1 is applied, which is covered by an insulator layer 2, which in turn bears a gate electrode layer 3.

The unpatterned semiconductor layer 1 applied on the substrate, insulator layer 2 and gate electrode layer 3 that are illustrated correspondingly in FIG. 1a are subsequently patterned jointly. The patterning may be effected for example by means of removal using a laser or, as an alternative, by means of protective resist in lithographic or printing lithographic processes.

FIG. 2a shows the formation of the functional layers after the patterning described above. Both the semiconductor layer 10′, the insulator layer 11′ and the gate electrode layer 12′ are present in patterned fashion. In accordance with FIG. 2a, the insulator layer 11′ may have undercut structures 6 which are suitable for preventing a short circuit between gate electrode layer 12′ and source and respectively drain electrode layers to be produced. Undercut structures 6 are to be understood to mean a layer which tapers at least in one of its sectional planes in the direction toward the substrate. Undercut structures 6 may be obtained not only by means of an etching process but also for example with the aid of a solvent.

In accordance with FIG. 2b, the source and drain electrode layers 13, 13′ are formed subsequent to the joint patterning of the semiconductor layer 1, of the insulator layer 2 and of the gate electrode layer 3. The source and drain electrode layers 13, 13′ may be formed analogously to the above description by means of direct or indirect layer-producing processes. In a direct process, by way of example, an alignment-tolerant conductive material 8 may be applied or printed on, which material flows as far as the substrate, forms the source and drain electrode layers 13, 13′ and establishes contact in the contact regions 14 to the patterned semiconductor layer 10′. In an alternative indirect process, it is possible, by way of example, to apply a patterned protective layer, in particular a protective resist layer, so that a conductive material 8 for forming the source and drain electrode layers 13 and 13′ can subsequently be applied in a targeted manner to the regions not covered by the protective layer.

A further third embodiment for the production of an organic transistor according to the invention is illustrated by way of example in FIG. 3a and FIG. 3b. This third embodiment essentially corresponds to the above-described second embodiment.

The starting point is, as described above with regard to FIG. 1, a substrate, on which an unpatterned, homogeneous semiconductor layer 1 is arranged, which is covered by an unpatterned insulator layer 2. In contrast the above description however, the insulator layer 2 is not covered by a gate electrode layer 3.

The unpatterned semiconductor layer 1 and insulator layer 2 borne by the substrate are subsequently patterned jointly. The patterning may be effected for example by means of removal using a laser or, as an alternative, by means of protective resist in lithographic or printing lithographic processes.

FIG. 3a shows the formation of the functional layers after the patterning described above. Both the semiconductor layer 15′ and the insulator layer 16′ are present in patterned fashion. In accordance with FIG. 3a, the insulator layer 16′ may likewise have undercut structures which can prevent a short circuit between a gate electrode layer to be produced and source and respectively drain electrode layers to be produced.

In accordance with FIG. 3b, a gate electrode layer 17′ and the source and drain electrode layers 18, 18′ are formed subsequent to the joint patterning of the semiconductor layer 1 and of the insulator layer 2. The gate electrode layer 17 and the source and drain electrode layers 18, 18′ may be formed analogously to the above description by means of direct or indirect layer-producing processes. In a direct process, by way of example, an alignment-tolerant conductive material 8 may be applied or printed on, which on the one hand flows as far as the substrate in order to form the source and drain electrode layers 18, 18′ and establishes contact in the contact regions 14 to the semiconductor, and which on the other hand forms the gate electrode layer 17 on the patterned insulator layer 16′. In an alternative indirect process, it is possible, by way of example, to apply a patterned protective layer, in particular a protective resist layer, so that the conductive material 8 for forming the gate electrode layer 17 and the source and drain electrode layers 18, 18′ can subsequently be applied in a targeted manner to the regions not covered by the protective layer.

In an advantageous manner, it is likewise possible to produce a contact location 19 between source or respectively drain electrode layer and gate electrode layer by applying more conductive material 8 at the desired contact location 19, or by applying conductive material 8 a second time at the contact location 19. A transistor having a contact between source and respectively drain electrode layers and gate electrode layer may be used as a diode.

The method described above is described in the context of a bar geometry of the organic transistor to be produced, that is to say that the source and respectively drain electrode layers lie opposite one another over the entire channel length. As an alternative, the method described above may likewise be used for fabricating an interdigital finger structure in which the individual contact fingers intermesh. The covering of the channel structure of the semiconductor layer by the insulator layer is crucial, so that a short circuit between source and respectively drain electrode layers and gate electrode layer is precluded.

It is evident in the context of the above description that the method presented in various embodiments does not require alignment having high accuracy in the individual fabrication steps and nevertheless enables the fabrication of a high-quality organic transistor.

An overlap between the gate electrode layer 3′ and source and drain electrode layers 4, 4′, as illustrated and set forth in FIG. 1c, is precluded since source and drain electrode layers 4, 4′ are only produced in regions which are not covered by the gate electrode layer 3′ and respectively the insulator layer 2′. The contact regions 5, which designate the contact regions of the semiconducting semiconductor region (that is to say channel region of the transistor) and the doped semiconductor regions, which are conductive, so that these regions serve as source and drain electrode layers 4, 4′, are well-defined according to the joint patterning of the gate electrode layer 3′ and insulator layer 2′.

The same applies with regard to the embodiments in accordance with FIG. 2b and FIG. 3b. An overlap between the gate electrode layer 12′ and source and respectively drain electrode layers 13, 13′ as illustrated in FIG. 2b, and an overlap between the gate electrode layer 17 and source and respectively drain electrode layers 18, 18′, as illustrated in FIG. 3b, are likewise precluded by virtue of the method. The contact regions 14 between semiconductor 10′ or 15′, respectively, and source and drain electrode layers 13, 13′ or 18, 18′, respectively, are likewise well-defined according to the joint patterning of the gate electrode layer, of the insulator layer and semiconductor layer or respectively of the insulator layer and semiconductor layer.

1. A method for the production of an organic transistor including a substrate with at least one unpatterned semiconductor layer on the substrate and an unpatterned insulator layer on the semiconductor layer;
the method comprising:
patterning of at least the insulator layer; and
forming at least source and drain electrode layers coupled to the semiconductor layer after the patterning of the insulator layer.

2. The method as claimed in claim 1 wherein an unpatterned gate electrode layer is on the insulator layer;
the method comprising:
jointly patterning the insulator layer and the gate electrode layer to uncover regions of the semiconductor layer; and
the forming the source and drain electrode layers is by doping the uncovered regions of the semiconductor layer.

3. The method as claimed in claim 2 wherein the doping of the uncovered regions of the semiconductor layer is performed with a doping chemical.

4. The method as claimed in claim 1 wherein an unpatterned gate electrode layer is on the insulator layer,
the method comprising:
jointly patterning the semiconductor layer, the insulator layer and the gate electrode layer to uncover regions of the substrate,
the forming of the source and drain electrode layers is by application of a conductive substance to the uncovered regions of the substrate.

5. The method as claimed in claim 1
including jointly patterning the semiconductor layer and the insulator layer so that regions of the substrate are uncovered; and
the forming of the source and drain electrodes is by joint formation of the source and drain electrode layers and of a gate electrode layer by application of a conductive substance to the uncovered regions of the substrate and to the insulator layer.

6. The method as claimed in claim 1 wherein the source and drain electrode layers are formed such that they do not overlap the gate electrode layer.

7. The method as claimed in claim 1 wherein the patterning is carried out by a laser, a lithographic process or a printing lithographic process.

8. The method as claimed in 1 wherein the substrate is a plastic film.

9. The method as claimed in claim 1 wherein the semiconductor layer is formed from an organic semiconducting substance.

10. The method as claimed in claim 1 wherein the insulator layer is formed from an organic electrically insulating substance.

11. An organic transistor made with the method of any one of claims 1 to 10.
